(19) United States
(12) Patent Application Publication
(10) Pub. No.: US 2026/0206306 A1
(43) Pub. Date: Jul. 16, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Ken-Ichi GOTO, Hsinchu (TW); Sheng-Chih LAI, Hsinchu (TW); Kenichi SANO, Hsinchu (TW)

(21) Appl. No.: 19/019,938

(22) Filed: Jan. 14, 2025

(51) Int. Cl. H10D 84/85; H01L 23/528; H10D 62/80; H10D 64/23; H10D 84/01

(52) U.S. Cl. CPC H10D 84/851; H10D 62/871; H10D 62/875; H10D 64/258; H10D 84/0167; H10W 20/43

(57) ABSTRACT

A device is formed. The device includes a device layer that has one or more active devices formed therein and a plurality of metallization layers M₀ to Mₙ over the device layer. The device further includes an oxide-semiconductor device formed between metallization layers Mₓ and Mₓ₊₁ of the plurality of metallization layers, wherein x≥1 and <n. The oxide-semiconductor device includes a first transistor with a first channel made of a first oxide-semiconductor material and a second transistor disposed over the first transistor, the second transistor includes a second channel made of a second oxide-semiconductor material, wherein the first and second oxide-semiconductor materials have opposite conductivity type.

### BACKGROUND

As the semiconductor industry introduces new generations of integrated circuits (IC) having higher performance and more functionality, the density of the elements forming the ICs increases, while the dimensions, sizes and spacing between components or elements are reduced. In the past, such reductions were limited only by the ability to define the structures photo-lithographically, device geometries having smaller dimensions created new limiting factors. With decreasing semiconductor device dimensions, improved semiconductor devices with improved sheet resistance, contact resistance, and capacitance are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, 8, 9, 10, 11, 12, 13, 14, 15, 16, 17, 18, 19, 20, 21, and 22 are cross-sectional side views of an oxide-semiconductor device structure formed in various stages of a fabrication process, in accordance with some embodiments.

FIG. 23 is a circuit diagram of an oxide-semiconductor semiconductor device;

FIGS. 24, 25, and 26 show the interconnection between stacked oxide-semiconductor devices in accordance with some embodiments.

FIG. 27 is a flow diagram showing a method for fabricating an oxide-semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Oxide semiconductors have attracted attention in 3D integration and 3D memory because of the characteristics of high mobility, low leakage, high voltage tolerance by low temperature process. The oxide semiconductors may be applied to various devices such field effect transistor (FET), for example, PMOS, NMOS, CFET, and other transistors which include an oxide-semiconductor channel, that is, a channel region made from oxide semiconductor materials. For example, oxide semiconductor materials such as indium gallium zinc oxide (IGZO), indium zinc oxide (IZO), zinc oxide (ZnO), or indium tin oxide (ITO) have been used to form the channels for n-type metal oxide semiconductor (NMOS), and tin oxide (SnO), nickel oxide (NiO), copper oxide (Cu₂O), and cobalt oxide (Co₃O₄) have been used to form channels for p-type MOS (PMOS). However, in the advanced node with high scaling, area space for forming the oxide semiconductors has become very limited. To take the advantages such as high mobility and low power consumption of the oxide semiconductors, according to some embodiments, the oxide semiconductors are formed in the BEOL interconnects. That is, devices such as CFET and various types of memories including oxide semiconductors are formed between the metallization layers Mₓ and Mₓ₊₁, for example, M₆ and M₇, of the BEOL interconnects.

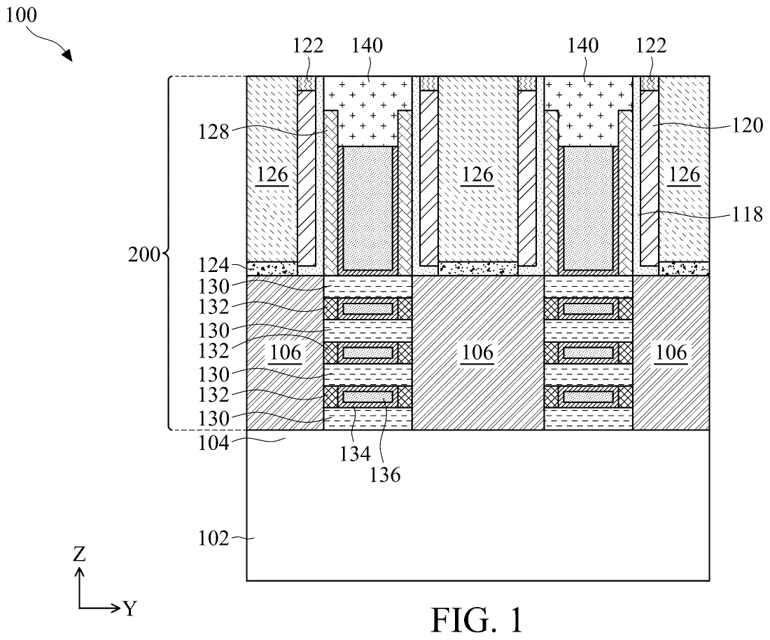

FIGS. 1-22 shows an embodiment of an oxide semiconductor device formed in a BEOL interconnection structure. The oxide semiconductor device includes an oxide semiconductor CFET (OSCFET) with a bottom oxide-semiconductor FET (OSFET) and a top OSFET stacked over the bottom OSFET. In the embodiment as shown in FIGS. 1-22, the top OSFET is in the form of a PMOS with an oxide-semiconductor channel, while the bottom OSFET is in the form of an NMOS with an oxide-semiconductor channel. It is appreciated that the positions of the PMOS and NMOS can be flipped according to some embodiments. Other structures such as planar, finFETs, and nanosheet, and other suitable structures may also be used for the top and bottom transistors.

As shown in FIG. 1, the semiconductor device structure 100 includes a substrate 102 having substrate portions 104 extending therefrom and source/drain (S/D) epitaxial features 106 disposed over the substrate portions 104. The substrate 102 may be a semiconductor substrate, such as a bulk silicon substrate. In some embodiments, the substrate 102 may be an elementary semiconductor, such as silicon or germanium in a crystalline structure; a compound semiconductor, such as silicon germanium, silicon carbide, gallium arsenic, gallium phosphide, indium phosphide, indium arsenide, and/or indium antimonide; other suitable materials; or combinations thereof. Possible substrates 102 also include a silicon-on-insulator (SOI) substrate. SOI substrates are fabricated using separation by implantation of oxygen (SIMOX), wafer bonding, and/or other suitable methods. The substrate portions 104 may be formed by recessing portions of the substrate 102. Thus, the substrate portions 104 may include the same material as the substrate 102. The substrate 102 and the substrate portions 104 may include various regions that have been suitably doped with impurities (e.g., p-type or n-type impurities). The dopants are, for example boron for a p-type field effect transistor (PFET) and phosphorus for an n-type field effect transistor (NFET). The S/D epitaxial features 106 may include a semiconductor material, such as Si or Ge, a III-V compound semiconductor, a II-VI compound semiconductor, or other suitable semiconductor material. Exemplary S/D epitaxial features 106 may include, but are not limited to, Ge, SiGe, GaAs, AlGaAs, GaAsP, SiP, InAs, AlAs, InP, GaN, InGaAs, InAlAs, GaSb, AlP, GaP, and the like. The S/D epitaxial features 106 may include p-type dopants, such as boron; n-type dopants, such as phosphorus or arsenic; and/or other suitable dopants including combinations thereof.

As shown in FIG. 1, S/D epitaxial features 106 may be connected by one or more semiconductor layers 130, which may be channels of a FET. In some embodiments, the FET is a nanostructure FET including a plurality of semiconductor layers 130, and at least a portion of each semiconductor layer 130 is wrapped around by a gate electrode layer 136. The semiconductor layer 130 may be or include materials such as Si, Ge, SiC, GeAs, GaP, InP, InAs, InSb, GaAsP, AlInAs, AlGaAs, InGaAs, GaInP, GaInAsP, or other suitable material. In some embodiments, each semiconductor layer 130 is made of Si. The gate electrode layer 136 includes one or more layers of electrically conductive material, such as polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. In some embodiments, the gate electrode layer 136 includes a metal. A gate dielectric layer 134 may be disposed between the gate electrode layer 136 and the semiconductor layers 130. The gate dielectric layer 134 may include two or more layers, such as an interfacial layer and a high-k dielectric layer. In some embodiments, the interfacial layer is an oxide layer, and the high-k dielectric layer includes hafnium oxide (HfO₂), hafnium silicate (HfSiO), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (AlO), aluminum silicon oxide (AlSiO), zirconium oxide (ZrO), titanium oxide (TiO), tantalum oxide (Ta₂O₅), yttrium oxide (Y₂O₃), silicon oxynitride (SiON), hafnium dioxide-alumina (HfO₂—Al₂O₃) alloy, or other suitable high-k materials.

The gate dielectric layer 134 and the gate electrode layer 136 may be separated from the S/D epitaxial features 106 by inner spacers 132. The inner spacers 132 may include a dielectric material, such as SiON, SiCN, SiOC, SiOCN, or SiN. Spacers 128 may be disposed over the plurality of semiconductor layers 130. The spacers 128 may include a dielectric material such as silicon oxide, silicon nitride, silicon carbide, silicon oxynitride, SiCN, silicon oxycarbide, SiOCN, and/or combinations thereof. In some embodiments, a self-aligned contact (SAC) layer 140 is formed over the spacers 128, the gate dielectric layer 134, and the gate electrode layer 136, as shown in FIG. 1. The SAC layer 140 may include any suitable material such as SiO, SiN, SiC, SiON, SiOC, SiCN, SiOCN, AlO, AlON, ZrO, ZrN, or combinations thereof.

A contact etch stop layer (CESL) 118 and an interlayer dielectric (ILD) layer 120 are disposed over the S/D epitaxial features 106, as shown in FIG. 1. The CESL 118 may include an oxygen-containing material or a nitrogen-containing material, such as silicon nitride, silicon carbon nitride, silicon oxynitride, carbon nitride, silicon oxide, silicon carbon oxide, the like, or a combination thereof. The materials for the ILD layer 120 may include an oxide formed by tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. A cap layer 122 may be disposed on the ILD layer 120, and the cap layer 122 may include a nitrogen-containing material, such as SiCN.

Conductive contacts 126 may be disposed in the ILD layer 120 and over the S/D epitaxial features 106, as shown in FIG. 1. The conductive contacts 126 may include one or more electrically conductive material, such as Ru, Mo, Co, Ni. W, Ti, Ta, Cu, Al, TiN and TaN. Silicide layers 124 may be disposed between the conductive contacts 126 and the S/D epitaxial features 106.

As shown in FIG. 1, the semiconductor device structure 100 may include the substrate 102 and a device layer 200 disposed over the substrate 102. The device layer 200 may include one or more devices, such as transistors, diodes, imaging sensors, resistors, capacitors, inductors, memory cells, combinations thereof, and/or other suitable devices. In some embodiments, the device layer 200 includes transistors, such as nanostructure transistors having a plurality of channels wrapped around by the gate electrode layer, as described above. The term nanostructure is used herein to designate any material portion with nanoscale, or even microscale dimensions, and has an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The channel(s) of the semiconductor device structure 100 may be surrounded by the gate electrode layer. The nanostructure transistors may be referred to as nanosheet transistors, nanowire transistors, gate-all-around (GAA) transistors, multi-bridge channel (MBC) transistors, or any transistors having the gate electrode layer surrounding the channels. In some embodiments, the device layer 200 includes devices such as planar FET, FinFET, complementary FET (CFET), forksheet FET, or other suitable devices.

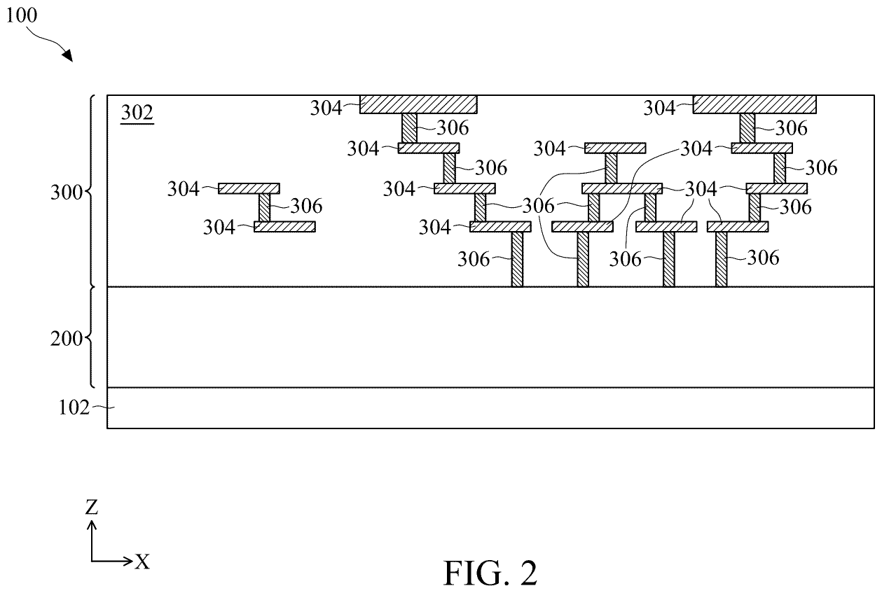

An interconnection structure 300 is formed over the device layer 200 and the substrate 102, as shown in FIG. 2. The interconnection structure 300 includes various conductive features, such as a first plurality of conductive features 304 and second plurality of conductive features 306, and an intermetal dielectric (IMD) layer 302 to separate and isolate various conductive features 304, 306. In some embodiments, the first plurality of conductive features 304 are conductive lines and the second plurality of conductive features 306 are conductive vias. The interconnection structure 300 includes multiple levels of the conductive features 304, and the conductive features 304 are arranged in each level to provide electrical paths to various devices in the device layer 200 disposed below. The conductive features 306 provide vertical electrical routing from the device layer 200 to the conductive features 304 and between conductive features 304. For example, the bottom-most conductive features 306 of the interconnection structure 300 may be electrically connected to the conductive contacts 126 (FIG. 1) and the gate electrode layer 136 (FIG. 1). The conductive features 304 and conductive features 306 may be made from one or more electrically conductive materials, such as metal, metal alloy, metal nitride, or silicide. For example, the conductive features 304 and the conductive features 306 are made from copper, aluminum, aluminum copper alloy, titanium, titanium nitride, tantalum, tantalum nitride, titanium silicon nitride, zirconium, gold, silver, cobalt, nickel, tungsten, tungsten nitride, tungsten silicon nitride, platinum, chromium, molybdenum, hafnium, other suitable conductive material, or a combination thereof.

The IMD layer 302 includes one or more dielectric materials to provide isolation functions to various conductive features 304, 306. The IMD layer 302 may include multiple dielectric layers embedding multiple levels of conductive features 304, 306. The IMD layer 302 is made from a dielectric material, such as SiOₓ, SiOₓC_{y}H_{z}, or SiOₓC_{y}, where x, y and z are integers or non-integers. In some embodiments, the IMD layer 302 includes a low-k dielectric material having a k value less than that of silicon oxide.

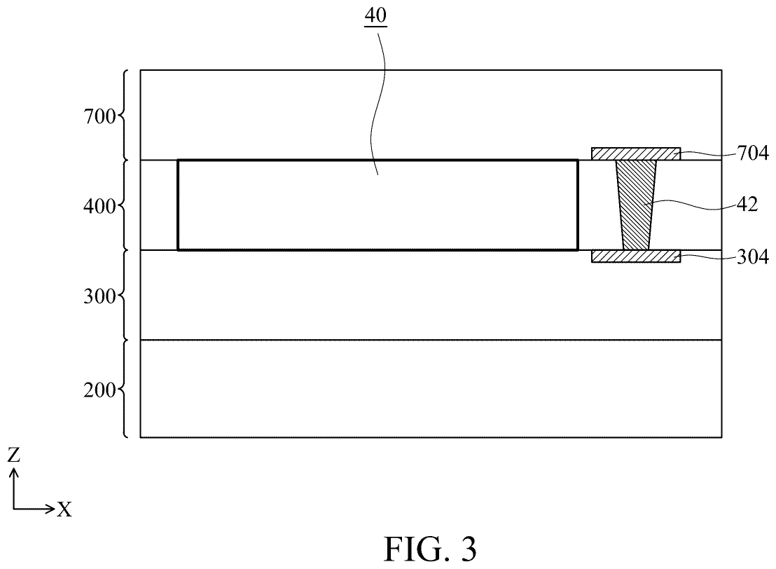

The process for forming the interconnection structure 300 may be referred to as the back-end-of-the-line (BEOL) process. The interconnection structure 300 provides wiring schemes that distribute clock and other signals, and provide power and ground and transfer electrical signals between devices, for example, devices formed in the device layer 200 during the front-end-of-the-line (FEOL) process. The interconnection structure 300 includes multiple metallization layers, for example, metallization layers M₀ to Mₓ. According to some embodiments, an OSCFET 40 is formed on the metallization layer Mₓ (x≥1) of the interconnection structure 300 in a dielectric layer, for example, an IMD layer 400, as shown in FIG. 3. An additional interconnection structure 700 that includes metallization layers, for example, Mₓ₊₁ to Mₙ, are formed over the OSCFET 40. Each of the metallization layers M₀ to Mₙ comprises metal lines, (for example, the conductive features 304 as shown in FIG. 2) organized horizontally in a dielectric material and interconnected vertically by means of via structures (for example, the vias 306 as shown in FIG. 2). The connection between the metallization layers Mₓ₊₁ and Mₓ or between the interconnection structures 300 and 700 may be achieved by conductive features 42 that extend through the ILD layer 400 and connect from the conductive feature 306 to the conductive feature 704 formed in the interconnection structures 300 and 700, respectively. The processes to form the IMD layer 400 and the interconnection structure 700 may also be BEOL processes. Interconnection structure 300, the IMD layer 400, and the interconnection structure 400 together may form the BEOL interconnection structure.

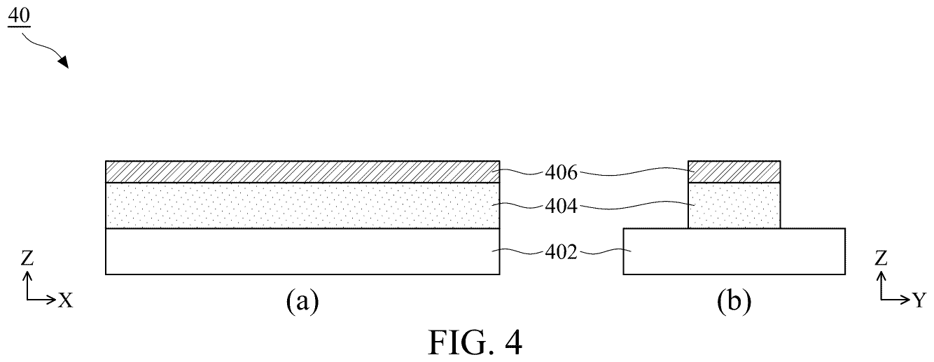

FIGS. 4-22 are cross sectional views of an OSCFET structure that includes a stacked of a bottom OSFET and a top OSFET between two metal layers of the BEOL interconnection structures 300 and 700. For example, the OSCFET 40 may be formed on the metallization layer Mₓ, and metallization layers Mₓ₊₁ to Mₙ are then formed over the OSCFET 40. Each of FIGS. 4-21 includes (a) showing an X-Z cross section of the OSCFET and (b) showing a Y-Z cross section of the OSCFET. In FIG. 4, a buffer layer 402 is formed on the metallization layer Mₓ. The buffer layer 402 may include an intermetal dielectric (IMD) layer formed on a metallization layer Mₓ. In one embodiment, the buffer layer 402 may be formed on the metallization layer M₆ formed over the device layer 200 when the combined number n of metallization layers M the interconnection structures 300 and 700 is 15. A sacrificial layer 404 is formed on the buffer layer 402. The sacrificial layer 404 is deposited at a compatible process temperature for the BEOL stage. For example, the sacrificial layer 404 may include a SiN layer formed at about 300° C. or lower by a plasma enhanced chemical vapor deposition (PECVD) process.

An oxide-semiconductor layer 406, for example, an IGZO layer, an amorphous IGZO layer, an IZO layer, a ZnO layer, or an ITO layer, may be formed on the sacrificial layer 404. The oxide-semiconductor layer 406 may be sputtered on the sacrificial layer 404 according to some embodiments. Physical vapor deposition (PVD) or atomic layer deposition (ALD) may be used for forming the oxide-semiconductor layer 406. The oxide-semiconductor layer 406 may function as the channel of an OSFET. As discussed above, materials such as IGZO, IZO, ZnO, or ITO may be used for forming the channels of an n-type OSFET when an NMOS is formed as the bottom OSFET. As it will be discussed layer, when the top OSFET includes a p-type OSFET, the oxide-semiconductor channels may be made from materials such as SnO, NiO, Cu₂O, and Co₃O₄.

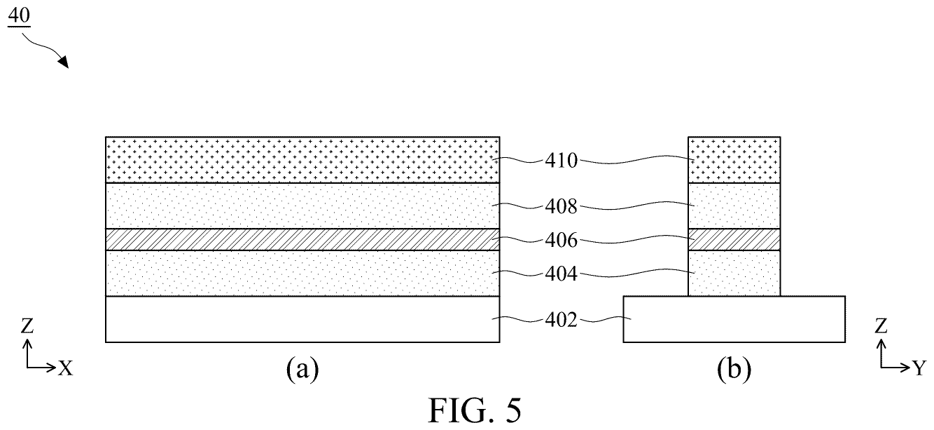

In FIG. 5, another sacrificial layer 408 may be formed on the oxide-semiconductor layer 406. The sacrificial layer 408 may be formed by the same process and operation conditions as those for forming the sacrificial layer 404. For example, the sacrificial layer 408 may include a SiN layer formed by PECVD or other suitable process at a temperature of about 300° C. The sacrificial layer 408 may have a thickness of about 150 nm according to one embodiment. An oxide layer 410 is then formed on the sacrificial layer 408. The oxide layer 410 may have a thickness of about 100 nm, for example.

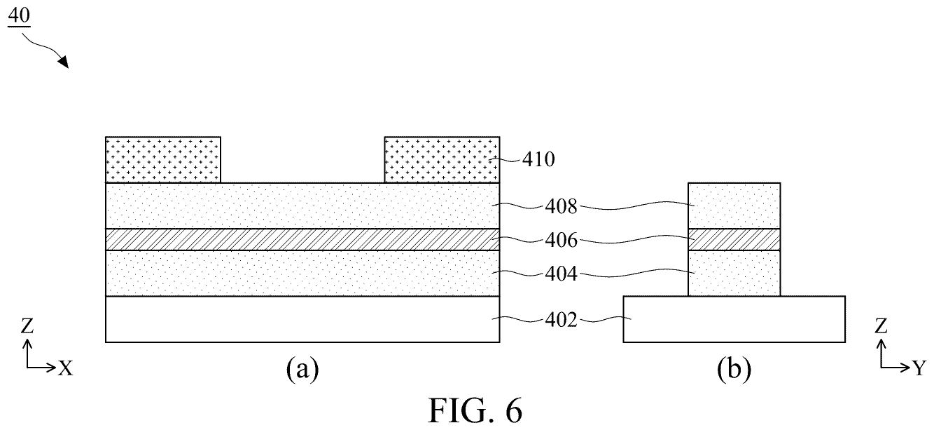

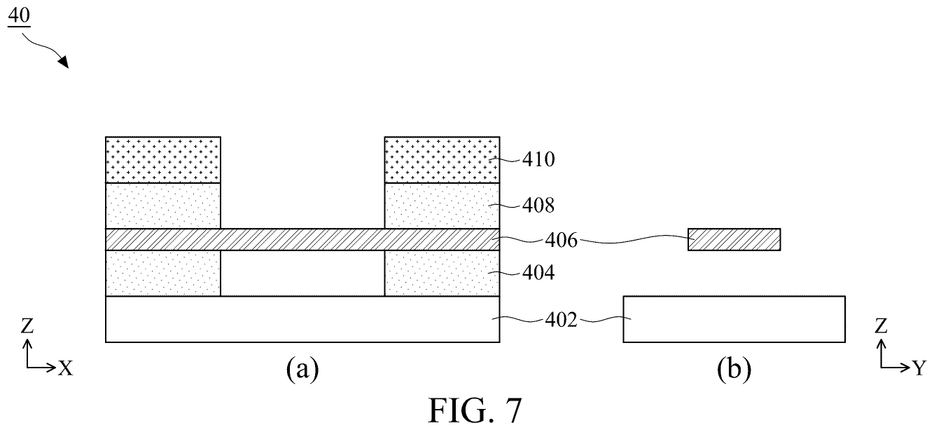

The oxide layer 410 is then patterned as shown in FIG. 6. The patterning process may include coating a photoresist layer on the oxide layer 410. A photolithography process is then performed to expose a portion of the oxide layer 410. A dry etching operation is performed to remove the exposed portion of the oxide layer 410. The photoresist layer is then removed. The exposed portions of the sacrificial layers 404 and 408 are then removed as shown in FIG. 7. According to one embodiment, removal of the sacrificial layers 404 and 408 may be achieved by a reactive ion etching (RIE) process such as an inductively coupled plasma (ICP) RIE process with a bottom RF power (RF_{bottom}) of 0 W. SF₆ may be used as an etchant for the ICP RIE operation. The remaining oxide layer 410 and the portion of the sacrificial layer 408 may serve as a composite field oxide layer (FOX) to insulate the metal gate structure and adjacent source/drain (S/D) regions to be formed subsequently, so as to cut the gate stack sidewall residue leakage path.

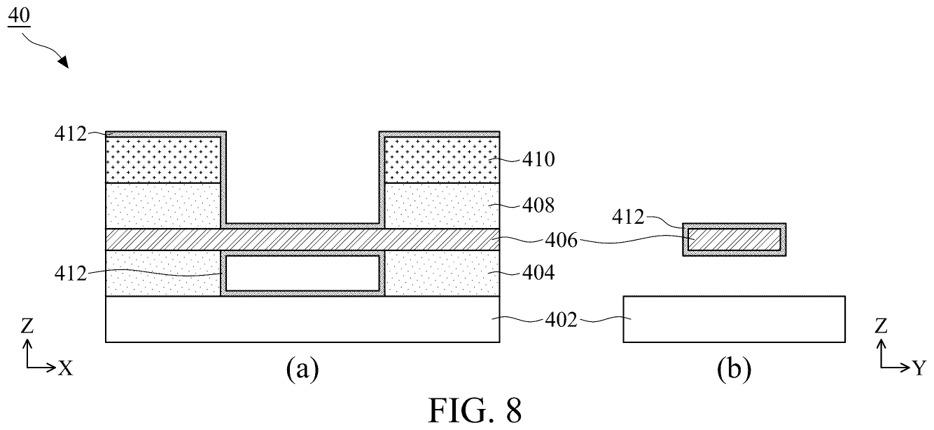

In FIG. 8, a gate dielectric layer 412 is formed to cover exposed surfaces of the oxide layer 410, the sacrificial layer 408, the oxide-semiconductor layer 406, the sacrificial layer 404, and the buffer layer 402. The gate dielectric layer 402 may be made from high-k dielectric materials such as Al₂O₃, ZrO₂, HfO₂ or other suitable materials. According to one embodiment, the gate dielectric layer 412 may include an Al₂O₃ layer formed by an ALD operation performed at a BEOL compatible temperature ranging from about 30^{o}C to about 300° C. For example, the gate dielectric layer 412 may include an Al₂O₃ layer formed by ALD at about 250° C. with about 100 reaction cycles.

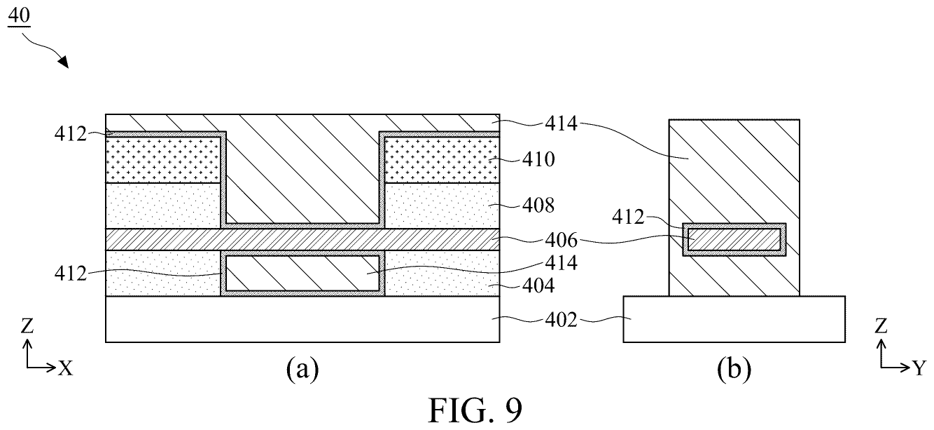

A gate electrode layer 414 is then formed over the gate dielectric layer 412 as shown in FIG. 9. In some embodiments, the gate electrode layer 414 may be formed from TiN material by ALD or physical vapor deposition (PVD). The gate electrode layer 414 may be formed in situ when the ALD process is selected. Alternatively, the gate electrode layer 414 may include a first portion formed by the ALD process and a second portion formed by a physical vapor deposition (PVD) process. For example, the gate electrode layer 414 may include a first TiN layer formed in situ by continuing the ALD process for forming the gate dielectric layer 412 at about 250° C. with about 100 reaction cycles, and a second TiN layer formed by a PVD process. The gate electrode layer 414 may also be formed by other suitable processes such as radio frequency (RF) PVD that provides more bottom coverage and minimal sidewall coverage, allowing the electrode gap-fill window to be effectively enlarged. In some embodiments, the gate electrode layer 414 may also be made of metals such as titanium (Ti), aluminum (Al), tantalum (Ta), or other metal composite such as Tantalum nitride (TaN), titanium aluminum (TiAl), tungsten nitride (WN).

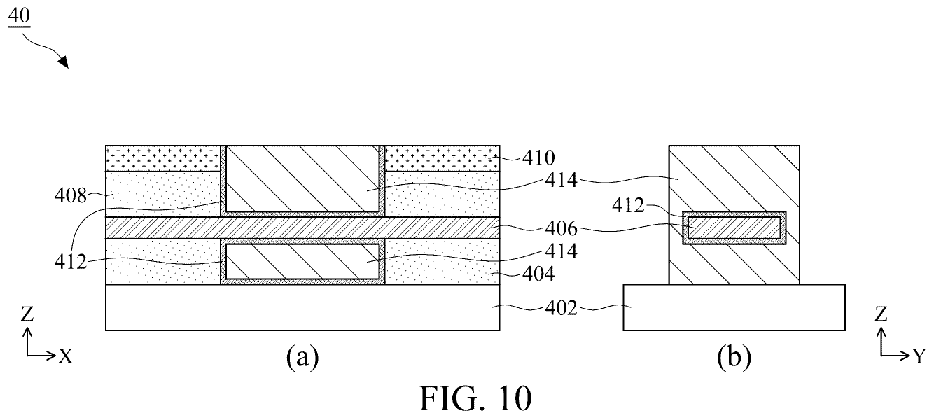

As shown in FIG. 10, a chemical mechanical polishing (CMP) process is then performed until the oxide layer 410 is exposed. In the embodiment as shown in FIG. 10 (see the cross section on the y-z plane in (b)), the FET has a gate-all-around (GAA) structure with an oxide-semiconductor channel 406 surrounded by a gate stack that includes the gate dielectric layer 412 and the gate electrode layer 414 (see (b) of FIGS. 8-10). In some embodiments, a barrier layer such as TaN layer (not shown) may be formed before the gate electrode layer 414 is formed. Each of the gate dielectric layer 412 and the gate electrode layer 414 may have a thickness of about 0.5 nm to about 5 nm.

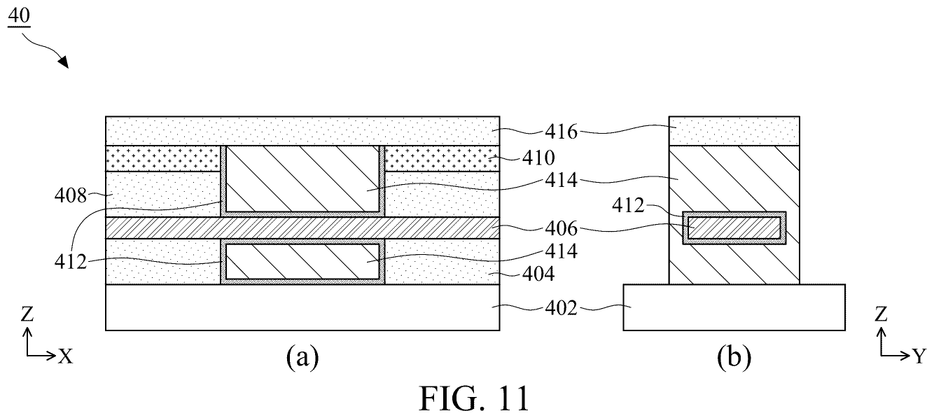

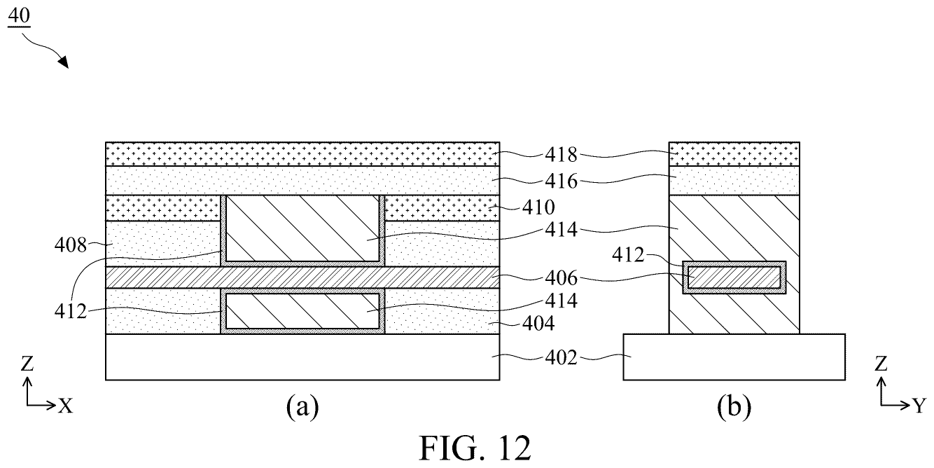

In FIG. 11, a dielectric layer 416 is formed to cover the gate electrode layer 414 and the oxide layer 410. The dielectric layer 416 may include a SiN layer formed by PECVD or other suitable process at a temperature of about 300° C. or lower. The dielectric layer 416 may have a thickness of about 150 nm. The dielectric layer 416 is then covered by an oxide layer 418 formed by PECVD at a temperature of about 300° C. or other suitable processes as shown in FIG. 12. According to some embodiment, the oxide layer 418 may have a thickness of about 100 nm.

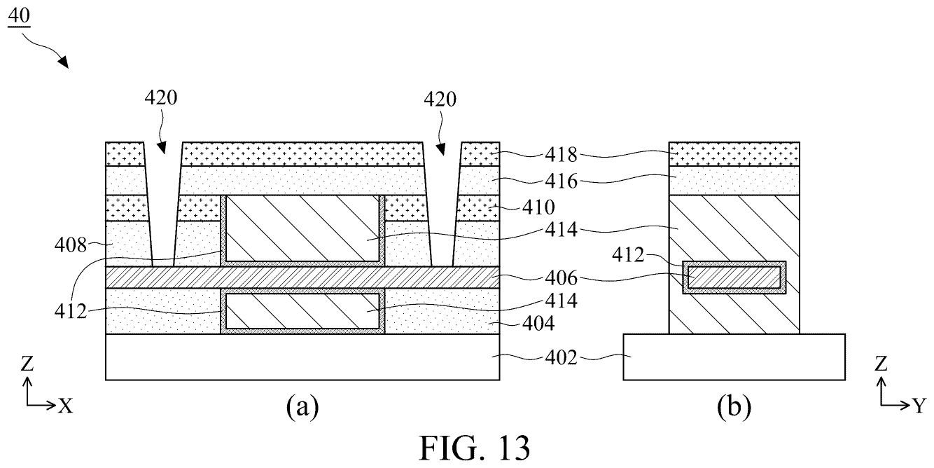

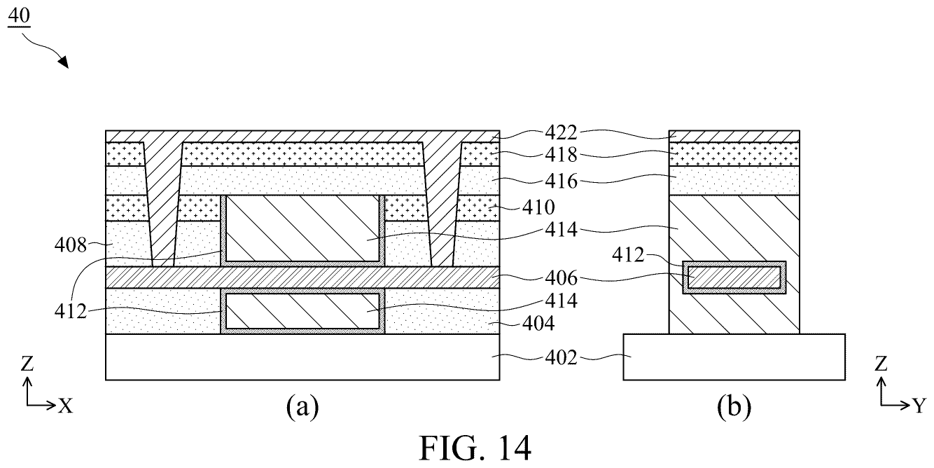

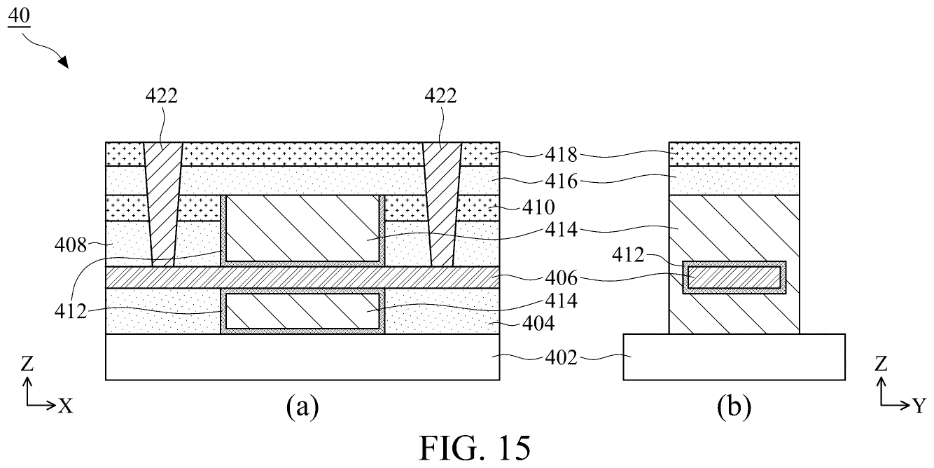

FIGS. 13-15 show the processes of defining source/drain regions. According to some embodiments, a photoresist layer (not shown) is coated on the oxide layer 418. The photoresist layer is patterned to define regions for forming the source/drain regions at two opposite sides of the metal gate structure, that is, the stack of the gate dielectric layer 412 and the gate electrode layer 414. The oxide layer 418, the dielectric layer 416, the oxide layer 410, and the sacrificial layer 412 are then etched, for example, dry etched, to form openings that expose the oxide-semiconductor layer 406 as shown in FIG. 13. In FIG. 14, the openings 420 are filled with conductive material, for example, nickel (Ni), tungsten (W), or other suitable metals. The conductive material formed in the openings 420 may be S/D regions 422. In this disclosure, a source region and a drain region are interchangeably used, and the structures thereof are substantially the same. Furthermore, source/drain region(s) may refer to a source or a drain, individually or collectively dependent upon the context. The method of depositing the conductive material may include CVD, ALD, or other suitable processes. A CMP process is then performed until the oxide layer 418 is exposed, and a pair of S/D regions 422 of the bottom transistor are formed as shown in FIG. 15.

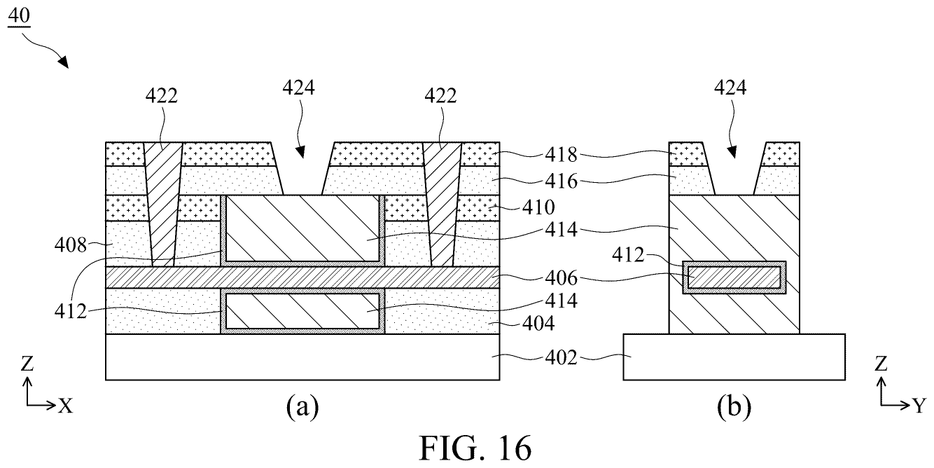

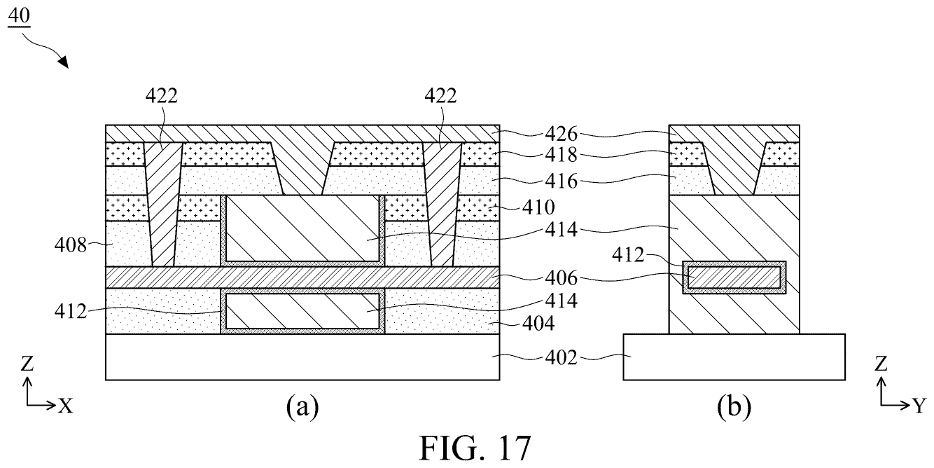

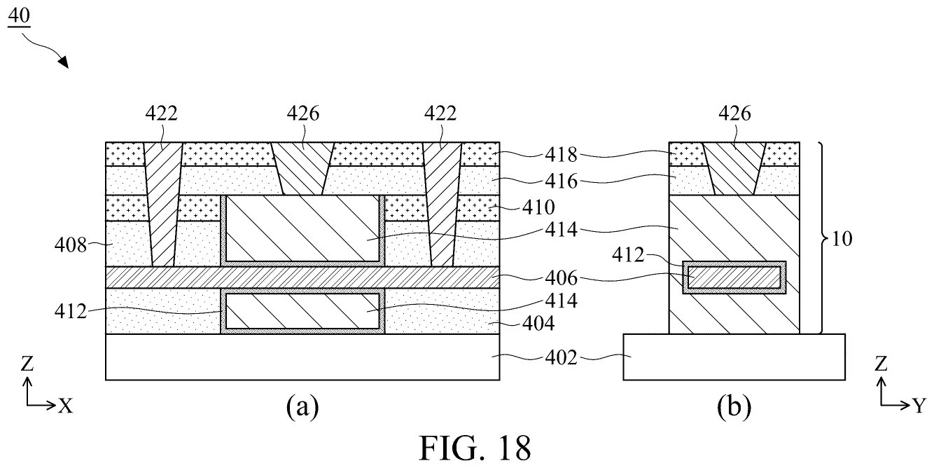

A photoresist layer (not shown) is coated and patterned with an opening and is aligned over the gate electrode layer 414. A dry etch operation is performed to remove the exposed oxide layer 418 the dielectric layer 416 underlying the exposed oxide layer 418 to form an opening 424 until the gate electrode layer 414 is exposed, as shown in FIG. 16. In FIG. 17, a metal layer 426 is then formed over the oxide layer 418 and to fill the opening 424. The metal layer 426 may be formed from Ti, Pt, Pd, Au, or other suitable metals. The metal layer 426 may be deposited by CVD, ALD, or other suitable processes. A CMP process is then performed until the oxide layer 418 is exposed, and the metal layer 426 may be a metal contact that interconnects with the gate structure (gate dielectric layer 412 and gate electrode layer 414) of the bottom transistor (OSFET) 10, as shown in FIG. 18.

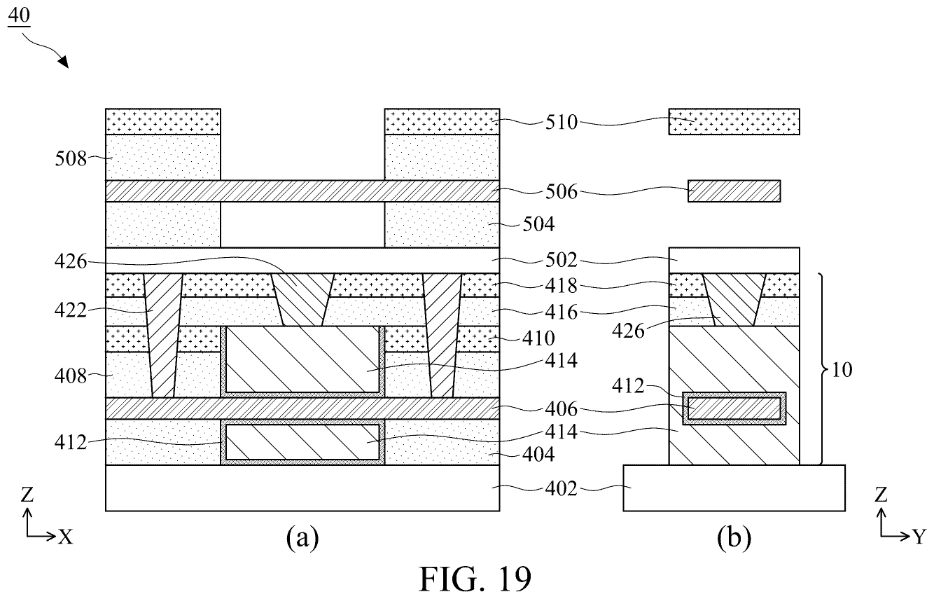

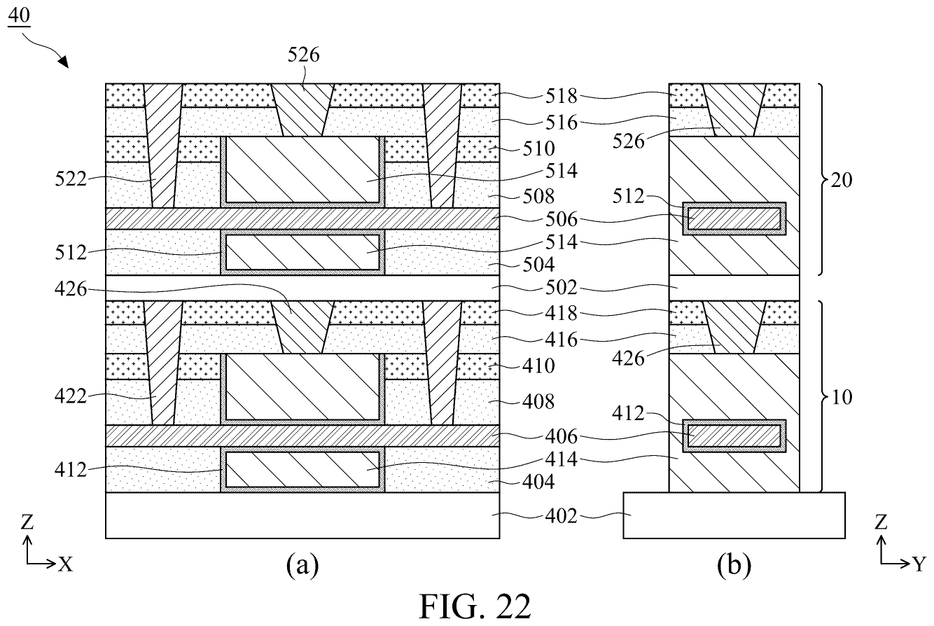

After the bottom transistor (OSFET) 10 is formed, a top transistor (OSFET) 20 (see FIG. 22) is formed to stack over the bottom transistor 10, as shown in FIGS. 19-22. In FIG. 19, a middle dielectric isolation (MDI) layer 502 is formed over the bottom transistor 10. The MDI layer 502 enables vertical integration of the top transistor 20 and the bottom transistor 10. The MDI layer 502 may serve as a etch stop layer during formation of various layers of the top transistor 20 in the subsequent processes. In one embodiment, the MDI layer 502 may be made of SiCN by PECVD or other suitable processes. A sacrificial layer 504 is formed on the MDI layer 502. The sacrificial layer 504 may include a SiN layer deposited at a temperature of about 300° C. by a PECVD process. An oxide-semiconductor layer 506, for example, a SnO layer, an NiO layer, a Cu₂O layer, a Co₃O₄ layer, or other suitable metal oxide layer may be formed on the sacrificial layer 504. The oxide-semiconductor layer 506 may be deposited on the sacrificial layer 504 by ALD or other processes such as PVD. When SnO is selected, the oxide-semiconductor layer 506 may be formed from the reaction between tetrakis(diethylamido) TDMA Sn and H₂O according to some embodiments at a temperature of about 300° C. or lower. In some embodiments, the oxide-semiconductor layer 406 includes an n-type oxide-semiconductor material, and the oxide-semiconductor layer 506 includes a p-type oxide-semiconductor material. In some embodiments, the oxide-semiconductor layer 406 includes a p-type oxide-semiconductor material, and the oxide-semiconductor layer 506 includes an n-type oxide-semiconductor material.

In FIG. 19, another sacrificial layer 508 may be formed on the oxide-semiconductor layer 506. The sacrificial layer 508 may be formed by the same process and operation conditions as those for forming the sacrificial layer 504. For example, the sacrificial layer 508 may include a SiN layer formed by PECVD or other suitable process at a temperature of about 300° C. The sacrificial layer 508 may have a thickness of about 150 nm according to one embodiment. An oxide layer 510 is then formed on the sacrificial layer 508. The oxide layer 510 may have a thickness of about 100 nm, for example. The oxide layer 510 is then patterned. The patterning process may include coating a photoresist layer (not shown) on the oxide layer 510. A photolithography process is then performed to expose a portion of the oxide layer 510. A dry etching operation is performed to remove the exposed portion of the oxide layer 510. The photoresist layer is then removed. The exposed portions of the sacrificial layers 504 and 508 are then removed as shown in FIG. 19. According to one embodiment, removal of the sacrificial layers 504 and 508 may be achieved by a reactive ion etching (RIE) process such as an inductively coupled plasma (ICP) RIE process with a bottom RF power (RF_{bottom}) of 0 W. SF₆ may be used as an etchant for the ICP RIE operation. The remaining oxide layer 510 may serve as a field oxide layer (FOX) to insulate the metal gate from the adjacent S/D regions formed subsequently. In the embodiment as shown in FIGS. 19-22, a composite FOX is formed by the stack of oxide layer 510 and the sacrificial layer 508 to cut the metal gate sidewall residue leakage path.

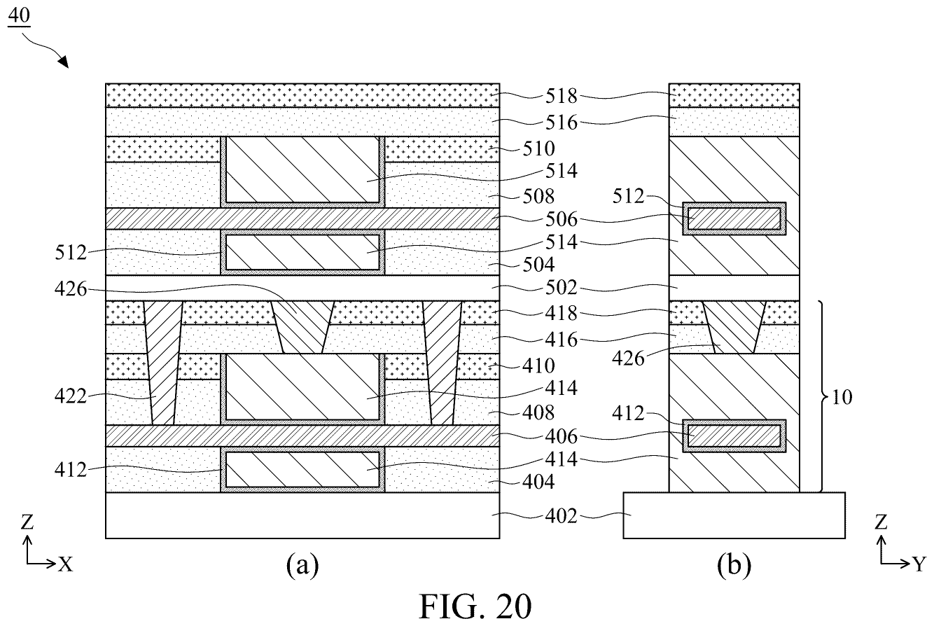

In FIG. 20, a gate dielectric layer 512 is formed to cover exposed surfaces of the oxide layer 510, the sacrificial layer 508, the oxide-semiconductor layer 506, the sacrificial layer 504, and the MDI layer 502. The gate dielectric layer 512 may be made from high-k dielectric materials such as Al₂O₃, ZrO₂, HfO₂ or other suitable materials. According to one embodiment, the gate dielectric layer 512 may include an Al₂O₃ layer formed by an ALD operation performed at a temperature ranging from about 30° C. to about 300° C. For example, the gate dielectric layer 512 may include an Al₂O₃ layer formed by ALD at about 250° C. with about 100 reaction cycles.

A gate electrode layer 514 is then formed over the gate dielectric layer 512. In some embodiments, the gate electrode layer 514 may be formed from TiN material by ALD or physical vapor deposition (PVD). The gate electrode layer 514 may be formed in situ when the ALD process used for forming the gate electrode layer 514. Alternatively, the gate electrode layer 514 may include a first portion formed in situ? and a second portion formed by a physical vapor deposition (PVD) process. For example, the gate electrode layer 514 may include a first TiN portion formed in situ by the ALD process performed at about 250° C. with about 100 reactions, and a second TiN portion formed by a PVD process. The gate electrode layer 514 may also be formed by other suitable processes such as radio frequency (RF) PVD that provides more bottom coverage and minimal sidewall coverage, allowing the electrode gap-fill window to be effectively enlarged.

A chemical mechanical polishing process (CMP) is then performed to remove the gate electrode layer 514 and gate dielectric layer 512 over the oxide layer 510 as shown in FIG. 20. In the embodiment as shown in FIG. 20 (the cross section on the y-z plane), the top transistor 20 includes a gate-all-around (GAA) structure with an oxide-semiconductor channel (oxide-semiconductor layer 506) surrounded by a gate stack that includes the gate dielectric layer 512 and the gate electrode layer 514 (see (b) of FIG. 20). In some embodiments, a barrier layer such as TaN layer (not shown) may be formed before the gate electrode layer 514 is formed.

A dielectric layer 516 is formed to cover the gate electrode layer 514 and the oxide layer 510. The dielectric layer 516 may include a SiN layer formed by PECVD at a temperature of about 300° C. or other suitable processes. The dielectric layer 516 may have a thickness of about 150 nm. The dielectric layer 516 is then covered by an oxide layer 518 formed by PECVD at a temperature of about 300° C. or other suitable processes. According to some embodiment, the oxide layer 518 may have a thickness of about 100 nm.

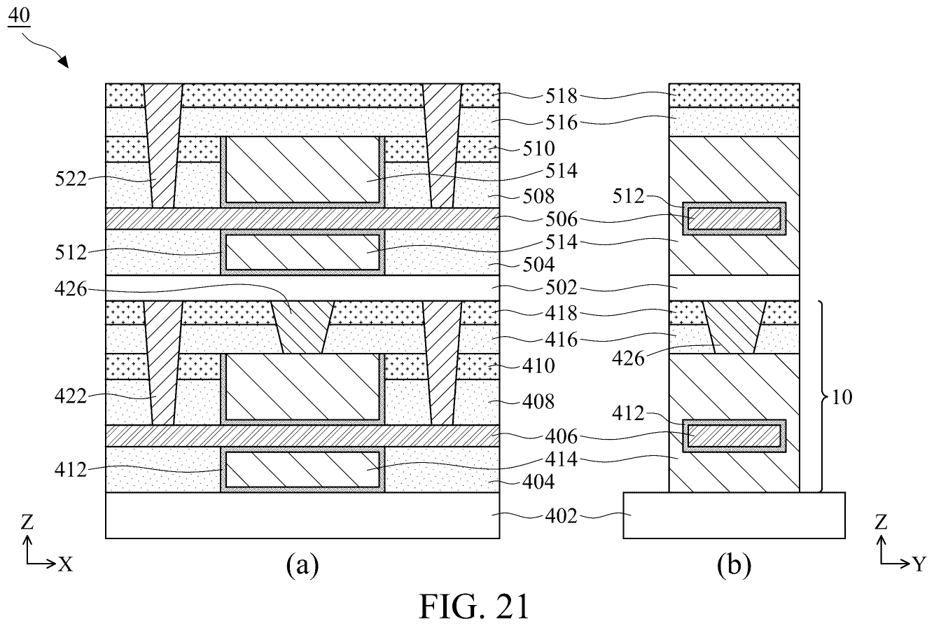

FIG. 21 shows the formation of S/D regions of the top transistor 20. A photoresist layer (not shown) is coated on the oxide layer 518. The photoresist layer is patterned to expose two regions for defining source/drain regions at two opposite sides of the gate structure that includes the gate dielectric layer 512 and the gate electrode layer 514. The oxide layer 518, the dielectric layer 516, the oxide layer 510, and the sacrificial layer 508 are then removed by a dry etching operation until two openings that expose the oxide-semiconductor layer 506 are formed. The openings are then filled with conductive material, including metal such as nickel (Ni) or tungsten (W). The method of depositing the conductive material 522 may include CVD, ALD, or other suitable processes. A CMP process is then performed until the oxide layer 518 is exposed, and the conductive material 522 in the two openings may be two S/D regions of the top transistor 20, as shown in FIG. 21.

A photoresist layer (not shown) is coated and patterned with an opening aligned over the gate electrode layer 514. A dry etch operation is performed to remove the oxide layer 518 exposed by the opening and the dielectric layer 516 underlying the exposed oxide layer 518 to form an opening that exposes the gate electrode layer 514. A metal layer 526 is then formed over the oxide layer 518 and to fill the opening as shown in FIG. 22. The metal layer 526 may be formed from nickel, tungsten, or other suitable metals or conductive materials. The metal layer 526 may be deposited by CVD, ALD, or other suitable processes. A CMP process is then performed until the oxide layer 518 is exposed, and the metal layer 526 may be a metal contact that interconnects with the gate structure (gate dielectric layer 512 and gate electrode layer 514) of the top transistor 20, as shown in FIG. 22.

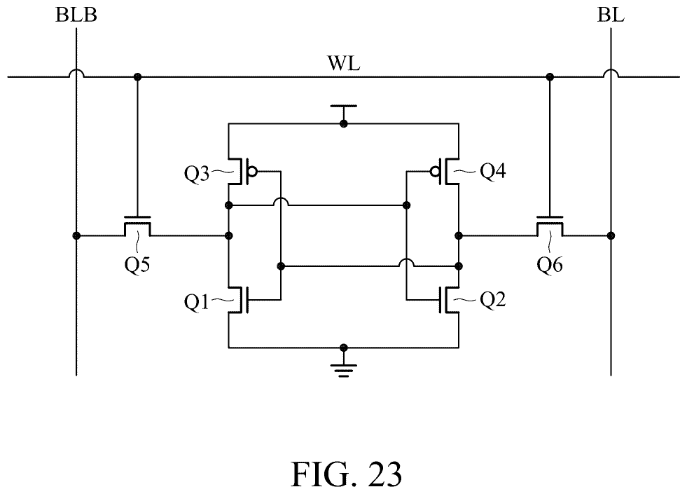

The OSCFET 40 may be used to form various types of memories such as static random access memories (SRAM) and magnetoresistive random access memories (MRAM). FIG. 23 shows a circuit diagram of a six-transistor (6T) SRAM including the OSCFET 40 made in the BEOL process according to some embodiments. As shown in FIG. 23, the 6T SRAM includes two pairs of top OSFETs (Q₁ and Q₃) and bottom OSFETs (Q₂ and Q₄) to form two cross-coupled inverters. Two auxiliary OSFETs (Q₅ and Q₆) serve as access or pass transistors to manage the storage unit access at time of write cycle or read cycle operation. The gate of the top OSFET Q₃ may be connected to gate of the bottom OSFET Q₁ of the same OSCFET. In other embodiments, the gate of the top OSFET Q₃ may also be connected to the gate of the bottom OSFET Q₂. Likewise, the gate of the top OSFET Q₄ may be connected to the gate of the bottom OSFET Q₂ of the same OSCFET in some embodiments or to the gate of the other bottom OSFET Q₁ in some other embodiments. The gate of the top OSFET Q₃ may be cross coupled with the gate of the bottom OSFET Q₂, and the gate of top OSFET Q₄ may be cross coupled with the gate of the bottom OSFET Q₁.

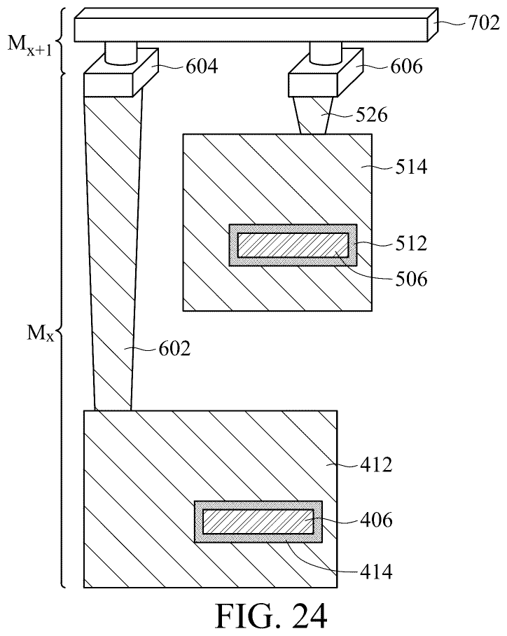

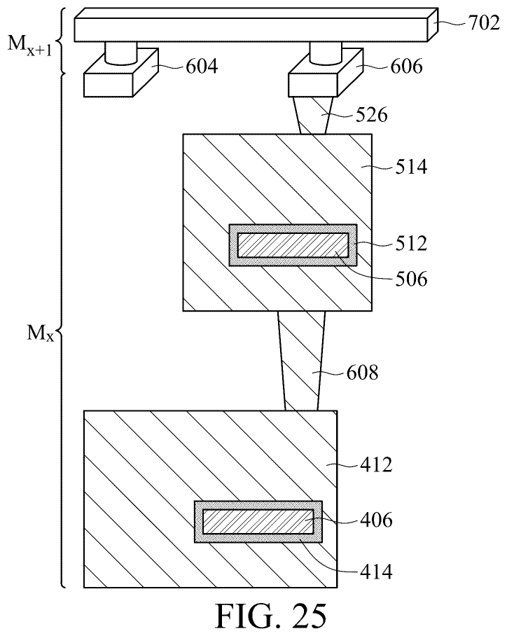

FIGS. 24 and 25 show two different ways to interconnect the gate of the top OSFET 20 with the bottom OSFET 10 according to some embodiments. The gates of the top and bottom OSFETs 20 and 10 may be referred to as Q₃ and Q₁ (or Q₄ and Q₂), respectively, referring to FIG. 23.

In FIG. 24, a metallization layer Mₓ₊₁ is formed over the metallization layer Mₓ in which the OSCFET (20 and 10) is formed. To connect the gate electrode layer 514 of the top OSFET 20 with the gate electrode layer 414 of the bottom OSFET 10 of the same OSCFET, two conductive features 604 and 606 are formed at the top of the metallization layer Mₓ. The conductive features 604 and 606 may be connected to a conductive feature 702 formed in the metallization layer Mₓ₊₁. According to some embodiments, the conductive features 604, 606, and 702 are made from copper, aluminum, aluminum copper alloy, titanium, titanium nitride, tantalum, tantalum nitride, titanium silicon nitride, zirconium, gold, silver, cobalt, nickel, tungsten, tungsten nitride, tungsten silicon nitride, platinum, chromium, molybdenum, hafnium, other suitable conductive material, or a combination thereof. The conductive feature 606 may be directly connected to the metal layer 526 extending from the gate electrode 514 of the top OSFET 20. A conductive feature 602 in the form of a metal plug may extend from the conductive feature 604 to the gate electrode layer 412 of the bottom OSFET 10. As the conductive features 604 and 606 are interconnected via the conductive feature 702, the interconnection between gate electrode layers 514 and 414 can be established.

FIG. 25 shows another embodiment to establish the interconnection between the a top OSFET and a bottom OSFET of the same OSCFET. In FIG. 25, two conductive features 604 and 606 are formed at the top of the metallization layer Mₓ. The conductive features 604 and 606 may be connected to a conductive feature 702 formed in the metallization layer Mₓ₊₁. The metal layer 526 of the top OSFET 20 is connected to the conductive feature 606. A conductive feature 608 is formed to extend from the bottom side of the gate electrode 514 of the top OSFET 20 to the gate electrode layer 414 of the bottom OSFET 10. For example, the conductive feature 608 may include a middle via that extends through the MDI layer 502 to connect with the metal layer 426 of the bottom OSFET 10 referring to FIG. 23. Alternatively, the conductive feature 608 may include a middle via that extends through the MDI layer 502, the oxide layer 418, and the dielectric layer 416 to the gate electrode layer 414 of the bottom OSFET 10.

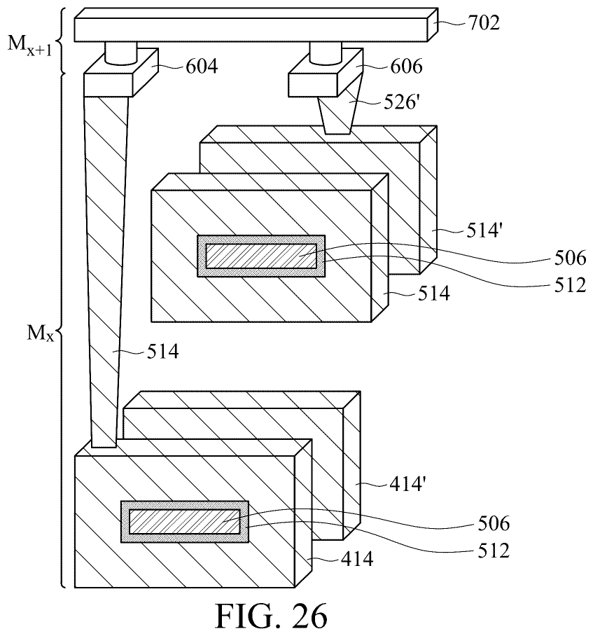

FIG. 26 shows an embodiment to interconnect the gate of the top OSFET of one of the OSCFETs and the gate of the bottom OSFET of another OSCFET. The SRAM as shown in FIG. 26 includes two OSCFETs, each including a top OSFET and a bottom OSFET, for example, an OSCFET that includes Q1 and Q3 and another OSCFET that includes Q₂ and Q₄. Similar to FIGS. 24 and 25, a conductive feature 702 is formed in the metallization layer Mₓ₊₁ to connect with two conductive features 604 and 606 formed at the top of the metallization layer Mₓ. The conductive feature 604 is connected to the gate electrode layer 414 of the bottom OSFET of a first OSCFET by a conductive feature 514. The conductive feature 606 is connected to a metal layer 526′ that connects with the gate electrode layer 514′ of the top OSFET of another OSCFET.

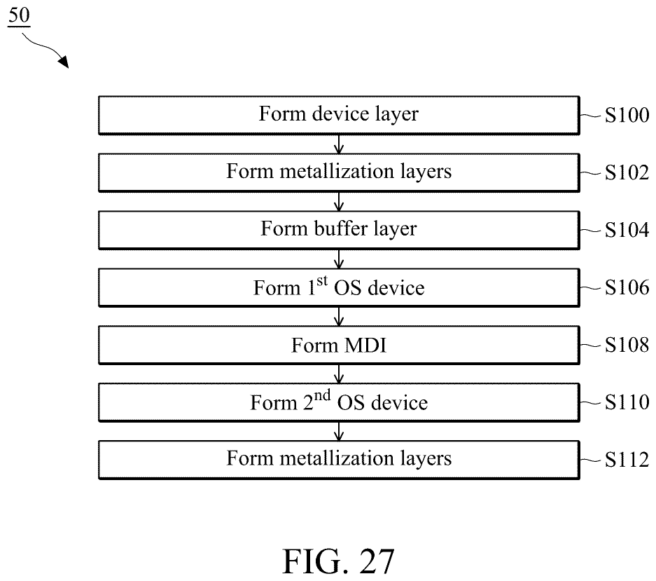

FIG. 27 is a flow diagram showing a method 50 for fabricating an oxide-semiconductor device, for example, an OSCFET, in accordance with some embodiments. At operation S100, a device layer is formed in the FEOL process. In some embodiments, the device layer includes devices such as planar FET, FinFET, nanostructure FET, complementary FET (CFET), forksheet FET, or other suitable devices. At operation S102, a number of metallization layers may be formed on the device layer in a BEOL process. The metallization layers provide wiring schemes that distribute clock and other signals and provide power and ground and transfer electrical signals between devices, for example, devices formed in the device layer during the front-end-of-the-line (FEOL) process.

At operation S104, a buffer layer is formed over the metallization layers. The buffer layer may be an IMD layer according to some embodiment. A first OSFET is then formed on the buffer layer at operation S106. The first OSFET may include an n-type FET or NMOS with a channel made of IGZO, IZO, ZnO, or indium tin oxide (ITO) according to some embodiments. The first OSFET may include a nanostructure transistor or a planar transistor. In some embodiments, the first OSFET may be a nanostructure transistor in which a gate electrode layer is disposed all around the oxide-semiconductor channel. In addition, FOX may be formed by composite dielectric layers such as combination of an oxide layer and a SiN layer as shown in FIG. 22 to cut off the leakage path from the gate sidewall towards source region and drain region. At operation S108, an MDI layer is then formed on the first OSFET to allow a 3D stack with a second OSFET formed subsequently. The MDI may serve as an etch stop layer that is difficult to be removed during formation of the second OSFET at operation S110. When the first OSFET is an n-type FET, the second OSFET may include a p-type FET with a channel made of tin oxide (SnO), nickel oxide (NiO), copper oxide (Cu₂O), or cobalt oxide (Co₃O₄). The second OSFET may also be a nanostructure transistor with the gate electrode layer disposed all around the oxide-semiconductor channel. At operation S112, upper metallization layers are then formed over the second OSFET.

Embodiments of the present disclosure provide a semiconductor device structure including an OSCFET 40 located in the BEOL interconnection structure. The semiconductor device structure includes a first OSFET located in the BEOL interconnection structure and a second OSFET located over the first OSFET in the BEOL interconnection structure. The first and second OSFET includes oxide-semiconductor layers as channels, and the oxide-semiconductor layers of the first and second OSFET have opposite conductivity types (n-type vs p-type). Some embodiments may achieve advantages. For example, by vertically stacking two OSFETs in the BEOL interconnection structure, the device density can be increased.

According to one embodiment, a device is formed. The device includes a device layer that has one or more active devices formed therein and a plurality of metallization layers M₀ to Mₙ over the device layer. The device further includes an oxide-semiconductor device formed between metallization layers Mₓ and Mₓ₊₁ of the plurality of metallization layers, wherein x≥1 and <n. The oxide-semiconductor device includes a first transistor with a first channel made of a first oxide-semiconductor material and a second transistor disposed over the first transistor, the second transistor includes a second channel made of a second oxide-semiconductor material, wherein the first and second oxide-semiconductor materials have opposite conductivity type.

According to another embodiment, a memory comprising at least an oxide-semiconductor complementary field-effect transistor (OSCFET) is provided. The OSCFET comprises an n-type oxide-semiconductor field-effect transistor (OSFET) and a p-type OSFET stacked with the n-type OSFET in a vertical direction. The OSCFET is sandwiched between two of a plurality of metallization layers formed in a back-end-of-the-line (BEOL) process after a device layer is formed in a front-end-of-the-line (FEOL) process.

According to yet another embodiment, a method is provided. One or more active devices are formed. A first set of metallization layers each comprising a plurality of conductive features is formed. A first oxide-semiconductor device is formed over the first set of metallization layers. A second oxide-semiconductor device is formed to stack over the first oxide-semiconductor device. A second set of metallization layers is formed over the second oxide-semiconductor device, each of the second set of metallization layers comprising a plurality of conductive features.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device, comprising:
a device layer including one or more active devices formed therein;
a plurality of metallization layers M₀ to Mₙ over the device layer; and
an oxide-semiconductor device formed between metallization layers Mₓ and Mₓ₊₁ of the plurality of metallization layers, wherein x≥1 and <n, the oxide-semiconductor device includes a first transistor with a first channel made of a first oxide-semiconductor material and a second transistor disposed over the first transistor, the second transistor includes a second channel made of a second oxide-semiconductor material, wherein the first and second oxide-semiconductor materials have opposite conductivity type.

2. The device of claim 1, further comprising a buffer layer formed on the metallization layer Mₓ on which the oxide-semiconductor device is formed.

3. The device of claim 1, wherein the first transistor is an NMOS, and the first oxide-semiconductor material includes indium gallium zinc oxide (IGZO), indium zinc oxide (IZO), zinc oxide (ZnO), or indium tin oxide (ITO).

4. The device of claim 1, wherein the first transistor is a PMOS, and the first oxide-semiconductor material includes tin oxide (SnO), nickel oxide (NiO), copper oxide (Cu₂O), or cobalt oxide (Co₃O₄).

5. The device of claim 1, wherein the first transistor and the second transistor are stacked over each other to form an oxide-semiconductor complementary field-effect transistor (OSCFET).

6. The device of claim 1, wherein the first transistor further comprises a gate electrode layer disposed around the first channel, a source region and a drain region at two opposite sides of the gate electrode layer.

7. The device of claim 6, wherein the first transistor further comprises a composite field oxide layer (FOX) between the gate electrode layer and the source region, and the composite FOX comprises an oxide layer and a silicon nitride layer.

8. The device of claim 6, wherein the first transistor further comprises a gate dielectric layer disposed between the gate electrode layer and the first channel.

9. A memory comprising at least an oxide-semiconductor complementary field-effect transistor (OSCFET), the OSCFET comprising:
an n-type oxide-semiconductor field-effect transistor (OSFET); and
a p-type OSFET stacked with the n-type OSFET in a vertical direction; wherein the OSCFET is sandwiched between two of a plurality of metallization layers formed in a back-end-of-the-line (BEOL) process after a device layer is formed in a front-end-of-the-line (FEOL) process.

10. The memory of claim 9, wherein each of the n-type OSFET and the p-type OSFET is a nanostructure transistor.

11. The memory of claim 9, wherein the n-type OSFET comprises a channel made of indium gallium zinc oxide (IGZO), indium zinc oxide (IZO), zinc oxide (ZnO), or indium tin oxide (ITO).

12. The memory of claim 9, wherein the p-type OSFET comprises a channel made of tin oxide (SnO), nickel oxide (NiO), copper oxide (Cu₂O), or cobalt oxide (Co₃O₄).

13. The memory of claim 9, further comprising a middle dielectric isolation layer to isolate the p-type OSFET from the n-type OSFET.

14. The memory of claim 11, further comprising another OSCFET and two auxiliary OSFETs.

15. The memory of claim 14, wherein the OSCFET and the another OSCFET form two cross-coupled inverters.

16. The memory of claim 14, wherein the two auxiliary OSFETs serve as access or pass transistors of the memory.

17. A method, comprising:
forming one or more active devices;
forming a first set of metallization layers each comprising a plurality of conductive features;
forming a first oxide-semiconductor device over the first set of metallization layers;
forming a second oxide-semiconductor device stacking over the first oxide-semiconductor device;
forming a second set of metallization layers over the second oxide-semiconductor device, each of the second set of metallization layers comprising a plurality of conductive features.

18. The method of claim 17, wherein further comprising:
forming a buffer layer on the first set of metallization layers before the first oxide-semiconductor device is formed; and
forming a middle dielectric isolation layer on the first oxide-semiconductor device before the second oxide-semiconductor device is formed.

19. The method of claim 17, wherein forming the first oxide-semiconductor device comprises:
depositing a first sacrificial layer;
depositing a first oxide-semiconductor layer on the first sacrificial layer;
depositing a second sacrificial layer on the first oxide-semiconductor layer;
removing portions of the first and second sacrificial layers to expose a portion of the first oxide-semiconductor layer; and
forming a gate electrode layer around the exposed portion of the first oxide-semiconductor layer.

20. The method of claim 19, wherein forming the first oxide-semiconductor device further comprises forming a source region in the second sacrificial layer, wherein the source region is in contact with the first oxide-semiconductor layer.
